(19) United States
(12) Patent Application Publication
(10) Pub. No.: US 2014/0331914 A1
(43) Pub. Date: Nov. 13, 2014

(54) APPARATUS FOR GROWING INGOT AND METHOD OF GROWING INGOT

(71) Applicant: LG SILTRON INC., Gyeongsangbuk-do (KR)

(72) Inventors: Ingu Kang, Daegu (KR); Sanghee Kim, Seoul (KR)

(21) Appl. No.: 13/821,006

(22) PCT Filed: Nov. 28, 2012
(86) PCT No.: PCT/KR2012/010187

§ 371 Date: Mar. 5, 2013

(30) Foreign Application Priority Data
Nov. 29, 2011 (KR) 10-2011-0125492

(51) Int. Cl. C30B 15/04

(52) U.S. Cl. CPC C30B 15/04
USPC 117/19; 117/208

(57) ABSTRACT

Provided is an ingot growing apparatus, which includes a crucible containing a silicon melt, a pulling device pulling a silicon single crystal ingot grown from the silicon melt, and a dopant supply unit disposed adjacent to the pulling device and for supplying a dopant during growing of the ingot. The neck portion may be doped at a concentration higher than that of the ingot through the dopant supply unit. Therefore, dislocation propagation velocity may be decreased and a propagation length may be shortened.

### CROSS-REFERENCE TO RELATED APPLICATIONS

The present application is a national phase application of P.C.T. application PCT/KR2012/010187 filed Nov. 28, 2012, which claims the priority benefit of Korean patent application 10-2011-0125492 filed Nov. 29, 2011, the disclosures of which are incorporated herein by reference.

### BACKGROUND OF THE INVENTION

1. Field of the Invention

The present disclosure relates to an apparatus for growing an ingot and a method of growing an ingot.

2. Description of the Related Art

In general, a process of manufacturing a wafer used for manufacturing a semiconductor device may include: a cutting process for slicing a silicon monocrystalline ingot; an edge grinding process for rounding an edge of a wafer formed by slicing the silicon monocrystalline ingot; a lapping process for planarizing a rough surface of the wafer due to the cutting process; a cleaning process for removing various impurities including particles, generated during the edge grinding process or the lapping process, from the wafer; a surface grinding process for the wafer to have a shape and a surface quality adapted for a subsequent process; and an edge polishing process for polishing the edge of the wafer.

Silicon monocrystalline ingots may be grown using a czochralski (CZ) method or a floating zone (FZ) method. The CZ method is commonly used for growing silicon monocrystalline ingots because large-diameter silicon monocrystalline ingots can be manufactured using the CZ method and the CZ method is economical.

The CZ method may be performed by immersing a seed crystal in silicon melt and then pulling the seed crystal at a low speed.

The silicon monocrystalline ingots are doped according to usages of the wafers. At this point, a dopant is dropped onto a surface of the silicon melt and is molten. In this case, the dropped dopant is not entirely molten in the silicon melt and a portion thereof is volatilized, which may unnecessarily increase a usage amount of the dopant and an inner contamination degree of an ingot growing apparatus. This may decrease the yield rate of ingots.

In particular, since antimony (Sb) has a low melting point, a phase change thereof quickly occurs. Thus, when an ingot is doped with Sb, an explosion due to a vapor pressure difference on a surface of silicon melt may occur. Hence, an additional process, such as a process of arbitrarily retreating a dopant and melting the dopant in a silicon melt, is needed to thereby increase a process time and a process cost.

### SUMMARY OF THE CLAIMED INVENTION

### Technical Problem

According to embodiments, a dopant is more efficiently provided to silicon melt, so as to grow a high quality silicon ingot.

### Technical Solution

In one embodiment, an ingot growing apparatus includes: a crucible that accommodates silicon melt; a pulling mechanism disposed above the crucible to move upward and downward; and a dopant provider part connected to the pulling mechanism to provide a dopant to the silicon melt, wherein the dopant provider part includes a bottom surface and a side surface, which are provided with one or more holes.

In another embodiment, an ingot growing method includes: preparing silicon melt; immersing a dopant provider part accommodating a dopant, into the silicon melt to provide the dopant to the silicon melt; providing the dopant to the silicon melt by introducing the silicon melt into the dopant provider part through a plurality of holes disposed in a bottom surface and a side surface of the dopant provider part; pulling the dopant provider part; and growing an ingot from the silicon melt.

The details of one or more embodiments are set forth in the accompanying drawings and the description below. Other features will be apparent from the description and drawings, and from the claims.

### Advantageous Effects of Invention

According to the embodiment, when a dopant contacts a silicon melt through a dopant provider part, the inside of an ingot growing apparatus is prevented from being contaminated by volatilization of the dopant. In addition, a dangerous accident such as an explosion due to a vapor pressure difference of the dopant on a surface of the silicon melt can be prevented. Thus, the yield rate of ingots grown from the silicon melt can be increased. In addition, the usage amount of an expensive dopant can be decreased, and silicon melt can be heavily doped.

The dopant provider part includes first holes in a bottom surface thereof and second holes in a side surface thereof. The inside of the dopant provider part can communicate with the outside thereof through the first and second holes, whereby the silicon melt can be introduced into the dopant provider part and be discharged therefrom through the first and second holes. That is, the dopant can contact the silicon melt. In particular, the dopant can be prevented from being lost from the dopant provider part, without an additional device for closing the first and second holes.

The dopant accommodated in the dopant provider part may have a stick shape. Thus, the silicon melt can be doped without a loss of the dopant through the first and second holes. In addition, since additional processes are unnecessary unlike typical granular dopants, a process time and a process cost can be decreased.

### BRIEF DESCRIPTION OF THE DRAWINGS

FIG. 1 is a cross-sectional view illustrating an ingot growing apparatus according to an embodiment.

FIG. 2 is an exploded perspective view illustrating a dopant provider part included in the ingot growing apparatus of FIG. 1.

FIG. 3 is a bottom view illustrating the dopant provider part included in the ingot growing apparatus of FIG. 1.

FIG. 4 is a perspective view illustrating dopants used in the ingot growing apparatus of FIG. 1.

FIGS. 5 and 6 are cross-sectional views illustrating an ingot growing method according to another embodiment.

FIG. 7 is a graph illustrating a comparison between specific resistivity of an embodiment with that of a comparative example.

### DETAILED DESCRIPTION

### Mode for the Invention

In the description of embodiments, it will be understood that when a layer (or film), region, pattern or structure is referred to as being ‘on’ or ‘under’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings.

In the drawings, the dimensions and size of each layer (or film), region, pattern or structure may be exaggerated, omitted, or schematically illustrated for convenience in description and clarity.

Hereinafter, an embodiment will be described in detail with reference to the accompanying drawings.

An ingot growing apparatus according to the current embodiment will be described in detail with reference to the accompanying drawings.

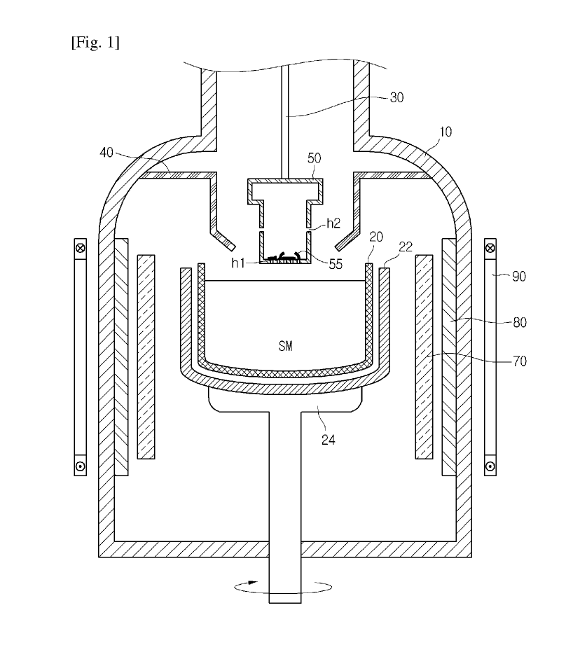

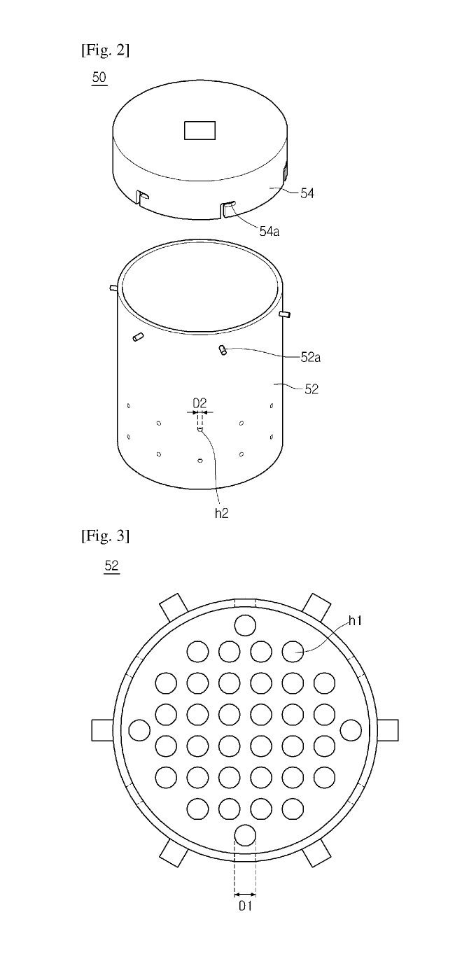

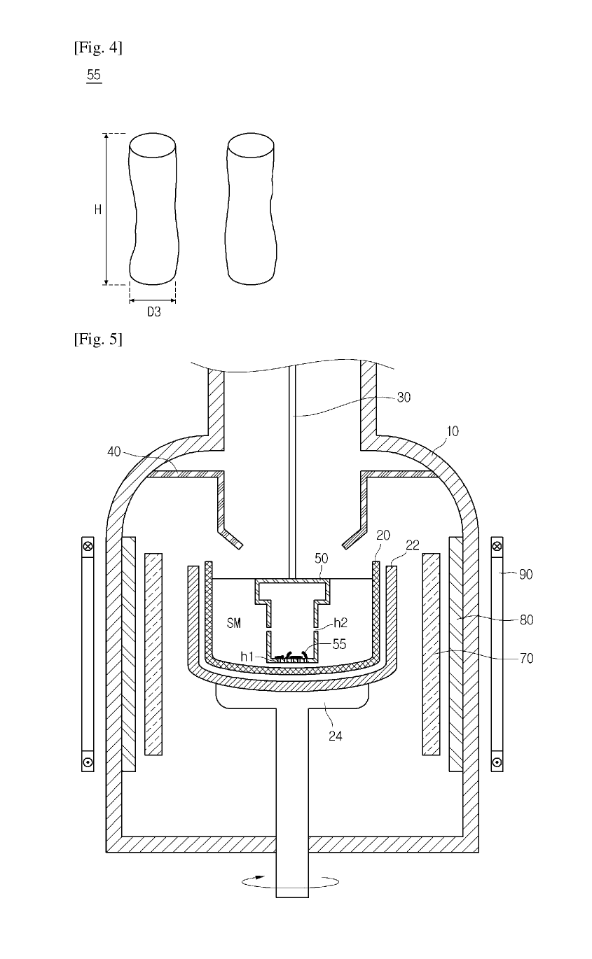

FIG. 1 is a cross-sectional view illustrating an ingot growing apparatus according to an embodiment. FIG. 2 is an exploded perspective view illustrating a dopant provider part included in the ingot growing apparatus according to the current embodiment. FIG. 3 is a bottom view illustrating the dopant provider part included in the ingot growing apparatus according to the current embodiment. FIG. 4 is a perspective view illustrating dopants according to the current embodiment.

Referring to FIG. 1, a silicon monocrystalline ingot manufacturing apparatus according to the current embodiment may be used in a czochralski (CZ) method among methods of manufacturing a silicon wafer.

The silicon monocrystalline ingot manufacturing apparatus includes a chamber 10, a quartz crucible 20 that contains silicon melt SM, a crucible supporter 22, a crucible rotation shaft 24, a dopant provider part 50, a pulling mechanism 30 pulling the dopant provider part 50, a heat shield 40 that blocks heat, a resistor heater 70, an insulator 80, and a magnetic field generator device 90.

The silicon monocrystalline ingot manufacturing apparatus will now be described in more detail.

The quartz crucible 20 may be installed in the chamber 10, and the crucible supporter 22 may support the quartz crucible 20. The silicon melt SM is accommodated in the quartz crucible 20. The quartz crucible 20 may include quartz, and the crucible supporter 22 may include graphite.

The quartz crucible 20 may be rotated clockwise or counterclockwise by the crucible rotation shaft 24.

The dopant provider part 50 is a component for stably supplying a dopant having high volatility and may be adjacent to the quartz crucible 20. The pulling mechanism 30, as a structure for moving the dopant provider part 50 upward and downward, may be connected to the upper surface of the dopant provider part 50.

According to the upward and downward movements of the pulling mechanism 30, the dopant provider part 50 connected to the pulling mechanism 30 are moved upward and downward.

The dopant provider part 50 will now be described in more detail with reference to FIGS. 2 and 3. The dopant provider part 50 may have a cylindrical shape to accommodate a dopant 55, but the shape of the dopant provider part 50 is not specifically limited.

The dopant provider part 50 may be formed of a silicon oxide (SiO2) such as quartz.

The dopant provider part 50 may have a plurality of holes. In particular, the dopant provider part 50 may have a bottom surface and a side surface surrounding the bottom surface, and the holes may be disposed in the bottom surface and the side surface. A plurality of first holes h1 may be disposed in the bottom surface. A plurality of second holes h2 may be disposed in the side surface.

The inside of the dopant provider part 50 can communicate with the outside thereof through the first and second holes h1 and h2, and the silicon melt SM can be introduced into the dopant provider part 50 and be discharged therefrom through the first and second holes h1 and h2. That is, the dopant 55 can contact the silicon melt SM.

A diameter D1 of the first holes h1 (a horizontal or vertical length of the first holes h1 unless the first holes h1 have a circular shape) and a diameter D2 of the second holes h2 (a horizontal or vertical length of the second holes h2 unless the second holes h2 have a circular shape) are smaller than a diameter D3 of dopants 55 (refer to FIG. 4), so as to prevent loss of the dopants 55 from the dopant provider part 50 through the first and second holes h1 and h2.

In addition, the dopant 55 can be prevented from being lost from the dopant provider part 50, without an additional device for closing the first and second holes h1 and h2. That is, since the dopant 55 is prevented from being lost through the first and second holes h1 and h2, it is unnecessary to close the first and second holes h1 and h2. In particular, the diameter D1 of the first holes h1 may range from about 5 mm to about 13 mm. When the diameter D1 of the first holes h1 is about 10 mm, the number of the first holes h1 may be about 32. The diameter D2 of the second holes h2 may be the same as the diameter D1 of the first holes h1, and the number of the second holes h2 may be about 16.

As illustrated in FIG. 3, an area taken by the first holes h1 in the bottom surface of the dopant provider part 50 may range about 40% to about 80% of an area of the bottom surface. When the area taken by the first holes h1 is smaller than about 40% of the area of the bottom surface, it may take a long time to melt the dopant 55 in the silicon melt SM for doping. When the area taken by the first holes h1 is greater than about 80% of the area of the bottom surface, the physical strength of the dopant provider part 50 may be decreased.

The area taken by the second holes h2 is smaller than the area taken by the first holes h1. This is because if the area taken by the second holes h2 disposed in the side surface is too large, gas may be discharged through volatilization of the dopant 55.

Referring to FIG. 4, the dopant 55 may have a cylindrical shape, and the outer circumferential surface of the cylindrical shape may be uneven. The diameter D3 of the dopant 55 (D3 may denote a horizontal or vertical width of the dopant 55 unless the upper or lower surface of the dopant 55 has a circular shape) may range about 15 mm to about 20 mm, and a height H of the dopant 55 may range about 40 mm to about 50 mm.

That is, since the dopant 55 has a stick shape, the dopant 55 is prevented from being lost from the first and second holes h1 and h2 during a doping process. In addition, since additional processes are unnecessary unlike typical granular dopants, a process time and a process cost can be decreased.

The silicon melt SM may be doped with the dopant 55. Accordingly, the electrical characteristics of a wafer manufactured from an ingot can be adjusted. The type of the dopant 55 depends on the type of a wafer to be manufactured. For example, when an N type wafer is manufactured, the dopant 55 may be phosphorous. For another example, when a P type wafer is manufactured, the dopant 55 may be boron.

The dopant provider part 50 may include an accommodating part 52 and a sealing part 54. The accommodating part 52 may accommodate the dopants 55, and the sealing part 54 may be removably coupled to the upper surface of the accommodating part 52. Thus, the upper surface of the accommodating part 52 may be sealed or opened according to the removal or coupling of the sealing part 54.

The accommodating part 52 may include protrusion parts 52a to couple to the sealing part 54. The sealing part 54 may include coupling recesses 54a to couple to the protrusion parts 52a. The sealing part 54 may seal the accommodating part 52 by means of the protrusion parts 52a and the coupling recesses 54a. However, embodiments are not limited thereto, and various structures for coupling the accommodating part 52 and the sealing part 54 may be provided. The accommodating part 52 and the sealing part 54 may be integrally formed.

When the dopant 55 contacts the silicon melt SM through the dopant provider part 50, the inside of the ingot growing apparatus is prevented from being contaminated by volatilization of the dopant 55. In addition, a dangerous accident such as an explosion due to a vapor pressure difference of the dopant 55 on a surface of the silicon melt SM can be prevented.

That is, a dopant is accommodated in the dopant provider part 50 formed of quartz, and the dopant provider part 50 is put in silicon melt. In this case, the dopant provider part 50 with the upper surface sealed prevents the inside of the ingot growing apparatus from being contaminated by volatilization due to contact between the dopant and the silicon melt. In addition, the outer surfaces of the dopant provider part 50 suppress sputtering of the dopant.

The resistor heater 70 may be adjacent to the crucible supporter 22 to heat the quartz crucible 20. The insulator 80 may be disposed outside of the resistor heater 70. The resistor heater 70 supplies heat needed to melt poly silicon into the silicon melt SM, and continually supplies heat to the silicon melt SM during a manufacturing process.

The silicon melt SM contained in the quartz crucible 20 has a high temperature, and emits heat from a surface thereof. When a large amount of heat is emitted from the surface of the silicon melt SM, it is difficult to maintain the silicon melt SM at an appropriate temperature needed for growing a silicon monocrystalline ingot. Thus, it is needed to minimize heat emitted from the surface of the silicon melt SM and prevent the emitted heat from being transferred to the upper side of the silicon monocrystalline ingot. To this end, the heat shield 40 is provided to maintain the silicon melt SM and the surface of the silicon melt SM in a high temperature environment.

The heat shield 40 may have one of various shapes to maintain a desired thermal environment for a stable crystal growth. For example, the heat shield 40 may have a hollow cylindrical shape to surround the silicon monocrystalline ingot. For example, the heat shield 40 may include graphite, graphite felt, or molybdenum.

The magnetic field generator device 90 may be disposed outside of the chamber 10 to apply a magnetic field to the silicon melt SM, thereby controlling convection of the silicon melt SM. The magnetic field generator device 90 may generate a magnetic field (MF) in a direction perpendicular to a crystal growth axis of a silicon monocrystalline ingot, that is, in a horizontal direction.

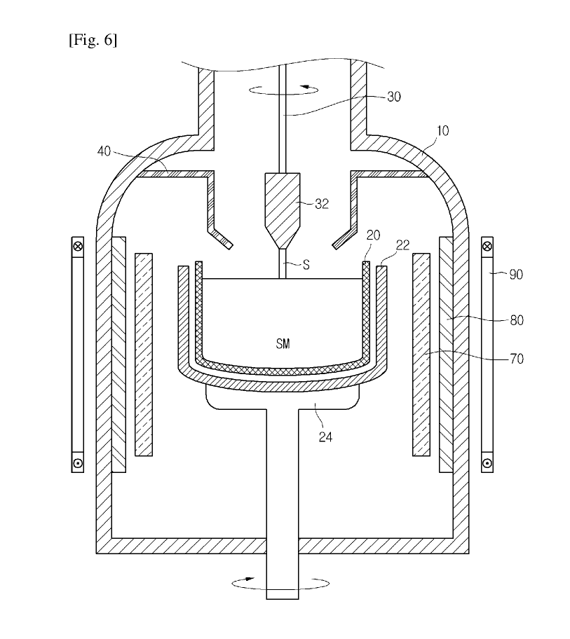

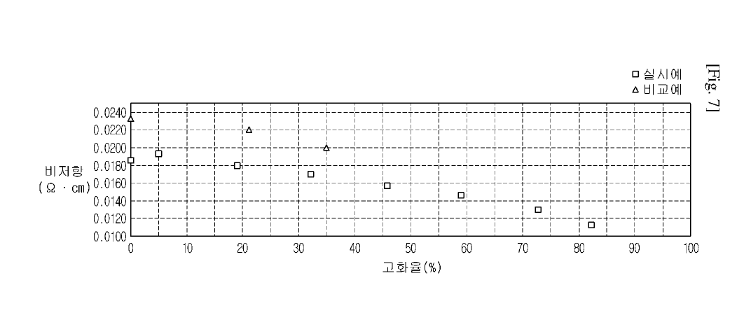

Hereinafter, an ingot growing method according to the current embodiment will be described with reference to FIGS. 5 and 6. For clarity and conciseness, detailed descriptions which are the same as or similar to the above descriptions are omitted.

FIGS. 5 and 6 are cross-sectional views illustrating an ingot growing method according to the current embodiment.

An ingot growing method according to the current embodiment includes: preparing the silicon melt SM; immersing the dopant provider part 50; providing the dopant 55; pulling the dopant provider part 50; and growing an ingot.

In the preparing of the silicon melt SM, the silicon melt SM may be prepared in a quartz crucible installed in a chamber.

In the immersing of the dopant provider part 50, the dopant provider part 50 may be immersed into the silicon melt SM. When the dopant provider part 50 accommodates the dopant 55, and is immersed into the silicon melt SM, the dopant 55 contacts the silicon melt SM to dope the silicon melt SM. Referring to FIG. 5, the dopant provider part 50 may be completely immersed in the silicon melt SM.

In the immersing of the dopant provider part 50, a descending speed of the dopant provider part 50 may range from about 900 mm/min to about 1100 mm/min. When the descending speed of the dopant provider part 50 is lower than about 900 mm/min, the dopant 55 may volatilize through the second holes h2 disposed in the side surface of the dopant provider part 50. When the descending speed of the dopant provider part 50 is higher than about 1100 mm/min, a process may be instable, and the dopant provider part 50 may be incompletely immersed in the silicon melt SM.

In the providing of the dopant 55, the dopant 55 may be molten in the silicon melt SM. Since the dopant 55 is disposed in the dopant provider part 50, an explosion due to volatilization or a vapor pressure difference of the dopant 55 can be prevented. In addition, the inside of an ingot growing apparatus is prevented from being contaminated, thereby increasing the yield rate of ingots.

In the pulling of the dopant provider part 50, the dopant provider part 50 may be lifted from the silicon melt SM.

Referring to FIG. 6, in the growing of the ingot, the ingot may be grown from the silicon melt SM.

At this point, the pulling mechanism 30 to which a seed crystal S is attached may be disposed above the quartz crucible 20 to pull the seed crystal S and be rotated in a direction opposite to a rotation direction of the crucible rotation shaft 24. Accordingly, the ingot is grown.

The features, structures, and effects described in the above embodiment are included in at least one embodiment of the present disclosure, and are not limited to only one embodiment. Further, features, structures, and effects described in each embodiment may be combined or modified in other embodiments by a person skilled in the art to which the embodiments belong. Thus, contents related to such combinations and modifications should be construed as being included in the scope of the present disclosure.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### Embodiment

Silicon melt was prepared in a crucible, and about 690 g of a dopant was prepared in a dopant provider part including quartz. After that, the dopant provider part was immersed into the silicon melt to dope the silicon melt.

### Comparative Example

About 860 g of a dopant was attached to a seed crystal having a rectangular parallelepiped shape. After that, the dopant is put in the silicon melt to dope the silicon melt.

Table 1 shows specific resistivity values of ingots grown according to the embodiment and the comparative embodiment.

TABLE 1

| | | Specific Resistivity |
|---|---|---|
| | Dopant Input Amount (g) | (mΩ · cm) |
| Embodiment | 690 g | 18.5 |
| Comparative Example | 860 g | 18.3 |

As shown in Table 1, about 860 g of the dopant was needed in the comparative example to reach a specific resistivity of about 18 mΩ/cm. However, about 690 g of the dopant was needed in the embodiment to reach a specific resistivity of about 18 mΩ·cm. That is, about 170 g of the dopant, which would otherwise volatilize, was saved.

TABLE 2

| | | Monocrystalline Yield |
|---|---|---|
| | Number of Retry Times | Rate (%) |
| Embodiment | 1.5 | 90 |
| Comparative Example | 2.7 | 78 |

As shown in Table 2, a difference in volatilized amount due to high concentration doping for reaching a target specific resistance value increased the number of retry times and decreased a monocrystalline yield rate in the comparative example. The number of retry times means the number of times of re-melting and re-growing an ingot when an ingot is lost. The number of retry times of the embodiment is smaller than that of the comparative example, and the monocrystalline yield rate of the embodiment is greater than that of the comparative example.

Referring to FIG. 7, although the amount of the dopant of the embodiment is smaller than that of the comparative example, specific resistivity of the ingot of the embodiment according to solidification ratio is smaller than that of the comparative example. Thus, the usage amount of an expensive dopant can be decreased.

### INDUSTRIAL APPLICABILITY

Since embodiments of the present disclosure can be applied to an ingot growing apparatus, the present disclosure is industrially applicable.

What is claimed is:

1. An ingot growing apparatus comprising:
a crucible that accommodates silicon melt;
a pulling mechanism disposed above the crucible to move upward and downward; and
a dopant provider part connected to the pulling mechanism to provide a dopant to the silicon melt,
wherein the dopant provider part comprises a bottom surface and a side surface, which are provided with one or more holes.

2. The ingot growing apparatus according to claim 1, wherein the dopant provider part comprises:
an accommodating part comprising the bottom surface and the side surface; and
a sealing part selectively closing an upper part of the accommodating part.

3. The ingot growing apparatus according to claim 2, wherein the dopant accommodated in the dopant provider part is greater than first holes disposed in the bottom surface of the accommodating part, and second holes disposed in the side surface of the accommodating part.

4. The ingot growing apparatus according to claim 3, wherein the dopant has a cylindrical shape or a bent shape, and a lower or upper surface of the dopant is greater than the first hole and the second hole.

5. The ingot growing apparatus according to claim 4, wherein a diameter or width of the lower or upper surface of the dopant ranges from about 15 mm to about 20 mm, and a height of the dopant ranges from about 40 mm to about 50 mm.

6. The ingot growing apparatus according to claim 3, wherein an area taken by first holes disposed in the bottom surface of the accommodating part ranges from about 40% to about 80% of an area of the bottom surface.

7. The ingot growing apparatus according to claim 6, wherein an area taken by the second holes is smaller than the area taken by the first holes.

8. The ingot growing apparatus according to claim 6, wherein a diameter or length of the first hole is smaller than a diameter or length of the second hole.

9. The ingot growing apparatus according to claim 6, wherein a diameter or length of the first hole ranges from about 5 mm to about 13 mm

10. The ingot growing apparatus according to claim 2, wherein as structures for selectively coupling the sealing part to an upper surface of the accommodating part, at least one protrusion part is disposed on the side surface of the accommodating part, and a coupling recess is disposed in a side surface of the sealing part to couple to the protrusion part.

11. The ingot growing apparatus according to claim 1, wherein the dopant provider part is formed of a silicon oxide.

12. An ingot growing method comprising:
preparing silicon melt;
immersing a dopant provider part accommodating a dopant, into the silicon melt to provide the dopant to the silicon melt;
providing the dopant to the silicon melt by introducing the silicon melt into the dopant provider part through a plurality of holes disposed in a bottom surface and a side surface of the dopant provider part;
pulling the dopant provider part; and
growing an ingot from the silicon melt.

13. The ingot growing method according to claim 12, wherein in the providing of the dopant to the silicon melt, a diameter or size of the dopant is greater than a size of the holes disposed in the dopant provider part such that the dopant is provided to the silicon melt in the dopant provider part.

14. The ingot growing method according to claim 12, wherein in the immersing of the dopant provider part into the silicon melt, the dopant provider part is descended at a speed ranging from about 900 mm/min to about 1100 mm/min.
